(19) United States
(12) Patent Application Publication
(10) Pub. No.: US 2026/0322328 A1
(43) Pub. Date: Oct. 15, 2026

(54) CURRENT AMPLIFIER CIRCUIT, AMPLIFIER CIRCUIT, AND IMAGE FORMING APPARATUS

(71) Applicant: Takuya SAKAMOTO, Kanagawa (JP)

(72) Inventor: Takuya SAKAMOTO, Kanagawa (JP)

(73) Assignee: Ricoh Company, Ltd., Tokyo (JP)

(21) Appl. No.: 19/467,155

(22) Filed: Feb. 2, 2026

(30) Foreign Application Priority Data
Mar. 18, 2025 (JP) 2025-043015

(51) Int. Cl. H03F 1/02; B41J 2/045; H03F 3/04

(52) U.S. Cl. CPC H03F 1/0205; B41J 2/04541; B41J 2/04548; B41J 2/0455; B41J 2/04581; H03F 3/04

(57) ABSTRACT

A current amplifier circuit includes: a first transistor including a first base terminal; and a second transistor including a second base terminal; and a capacitor coupling the first base terminal of the first transistors and the second base terminal of the second transistor, to perform a class-B operation.

### CROSS-REFERENCE TO RELATED APPLICATIONS

This patent application is based on and claims priority pursuant to 35 U.S.C. § 119(a) to Japanese Patent Application No. 2025-043015, filed on Mar. 18, 2025, in the Japan Patent Office, the entire disclosure of which is hereby incorporated by reference herein.

### BACKGROUND

### Technical Field

The present disclosure relates to a current amplifier circuit in a circuit for driving an inkjet head, an amplifier circuit, and an image forming apparatus including the amplifier circuit.

### Related Art

From the viewpoint of reducing power consumption, a class-B amplifier circuit or a class-AB amplifier circuit may be used as a circuit for driving an inkjet head in an inkjet image forming apparatus.

The amplifier circuit to be used for an inkjet head includes a voltage amplification unit, a current amplification unit, and a feedback unit. The voltage amplification unit performs amplification operation in multiple stages including a preceding-stage amplification unit and a subsequent-stage amplification unit. The feedback unit includes a low-pass unit, and combines, with a feedback signal, a low-frequency component of a voltage signal that has been voltage-amplified by the preceding-stage amplification unit, the low-frequency component corresponding to a characteristic of the low-pass unit. It is possible to provide a recording head drive circuit that can more easily and stably supply power to a load element of a recording head while preventing deterioration of a voltage waveform.

However, when thermal stability is lost due to nonlinear characteristics of a bias circuit diode and a drive circuit transistor in a class-B amplifier circuit, operation may shift to class-AB operation. When operation shifts to class-AB operation, loss occurs due to idling current, and loss occurs due to flow-through current at an output stage. As a result, power consumption increases. Therefore, there has been demand for a technique for improving operation stability in class-B amplifier circuits.

### SUMMARY

The present disclosure disclosed herein provides a current amplifier circuit including a first transistor including a first base terminal; and a second transistor including a second base terminal; and a capacitor coupling the first base terminal of the first transistors and the second base terminal of the second transistor, to perform class-B operation.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a schematic diagram illustrating a configuration of an image forming apparatus;

FIG. 2 is a diagram illustrating a system configuration of an image forming unit;

FIG. 3 is a circuit diagram of a current amplifier circuit;

FIGS. 4A and 4B are diagrams describing a feedback method of an amplifier circuit;

FIG. 5 is a circuit diagram of a current amplifier circuit according to a first modification;

FIG. 6 is a circuit diagram of a current amplifier circuit according to a second modification;

FIG. 7 is a circuit diagram of a current amplifier circuit according to a third modification;

FIG. 8 is a circuit diagram of a current amplifier circuit according to a fourth modification;

FIG. 9 is a circuit diagram of a current amplifier circuit according to a fifth modification;

FIG. 10 is a circuit diagram of a current amplifier circuit according to a sixth modification; and

FIG. 11 is a circuit diagram of a current amplifier circuit according to a seventh modification.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

Although embodiments of the present disclosure are described below, the present disclosure is not limited thereto. In the drawings referred to below, the same reference numerals are used for the common elements, and descriptions thereof are omitted as appropriate.

The present disclosure provides a current amplifier circuit, an amplifier circuit, and an image forming apparatus that achieve an increase in speed and improvement in stability in a class-B operation amplifier circuit that drives an inkjet head.

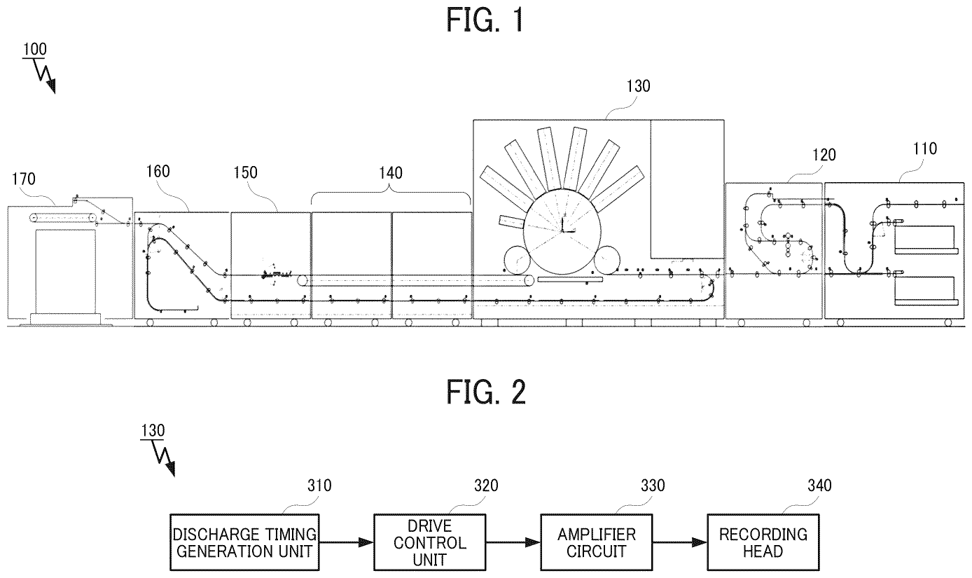

FIG. 1 is a schematic diagram illustrating a configuration of an image forming apparatus 100. The image forming apparatus 100 is an apparatus that forms an image on a sheet by an inkjet method. The image forming apparatus 100 illustrated in FIG. 1 is configured as a line printer type image forming apparatus. The image forming apparatus 100 includes a sheet feeding unit 110, a pre-coating unit 120, an image forming unit 130, a drying unit 140, a cooling straightening unit 150, a reversing unit 160, and a sheet ejection unit 170.

The sheet feeding unit 110 is a device that stores a sheet on which an image is to be formed and conveys the sheet to a subsequent unit. The pre-coating unit 120 is a device that applies a liquid medicine (pre-coating liquid) that prevents blurring of an image to a surface of the sheet conveyed from the sheet feeding unit 110. The pre-coating unit 120 can apply the pre-coating liquid to both sides or one side of the sheet as necessary.

The image forming unit 130 is a device that forms an image on a sheet by an inkjet method.

The image forming unit 130 can execute processing of forming an image on the basis of, for example, a print job received from an information processing apparatus or the like.

The drying unit 140 is a device that dries a sheet conveyed from the image forming unit 130. The drying unit 140 can dry ink discharged on the sheet. The cooling straightening unit 150 is a device that straightens a dry wrinkle generated when the dried sheet is cooled.

The reversing unit 160 is a device that switches back the sheet to reverse the front and back surface of the sheet. The reversing unit 160 can reverse a sheet and convey the sheet to the image forming unit 130 when executing a print job for performing duplex printing. The sheet ejection unit 170 is a device that ejects a sheet subjected to a series of image forming processes.

The configuration of the image forming apparatus 100 illustrated in FIG. 1 is an example. The image forming apparatus 100 need not be configured as a line printer type image forming apparatus, and may be, for example, a multi-function peripheral (MFP) or a home inkjet printer.

Next, a system configuration of the image forming unit 130 will be described with reference to FIG. 2. FIG. 2 is a diagram illustrating a system configuration of the image forming unit 130. As illustrated in FIG. 2, the image forming unit 130 includes a discharge timing generation unit 310, a drive control unit 320, an amplifier circuit 330, and a recording head 340. As a result of operation of each constituent element illustrated in FIG. 2, the image forming unit 130 can form an image on a sheet. The recording head 340 is referred to also as “an inkjet head” or “a liquid discharge head” that discharges a liquid such as ink to a target object such as a sheet.

The discharge timing generation unit 310 generates data indicating a timing at which the recording head 340 discharges ink, based on image data related to a print job.

The drive control unit 320 outputs a control signal for causing a device such as the recording head 340 (inkjet head) to operate, based on the timing data generated by the discharge timing generation unit 310.

The amplifier circuit 330 is a circuit that amplifies the control signal output from the drive control unit 320 and outputs the amplified control signal to the recording head 340. The amplifier circuit 330 can prevent distortion of the control signal and stabilize operation of the recording head 340. The amplifier circuit 330 includes a voltage amplifier circuit 332 and a current amplifier circuit 331. The voltage amplifier circuit 332 amplifies voltage of the control signal output from the drive control unit 320, and generates a drive voltage required by an ink discharge mechanism (such as a piezoelectric element or a thin-film element) in the recording head 340. The current amplifier circuit 331 generates drive current.

The recording head 340 is a device that discharges ink droplets based on the control signal.

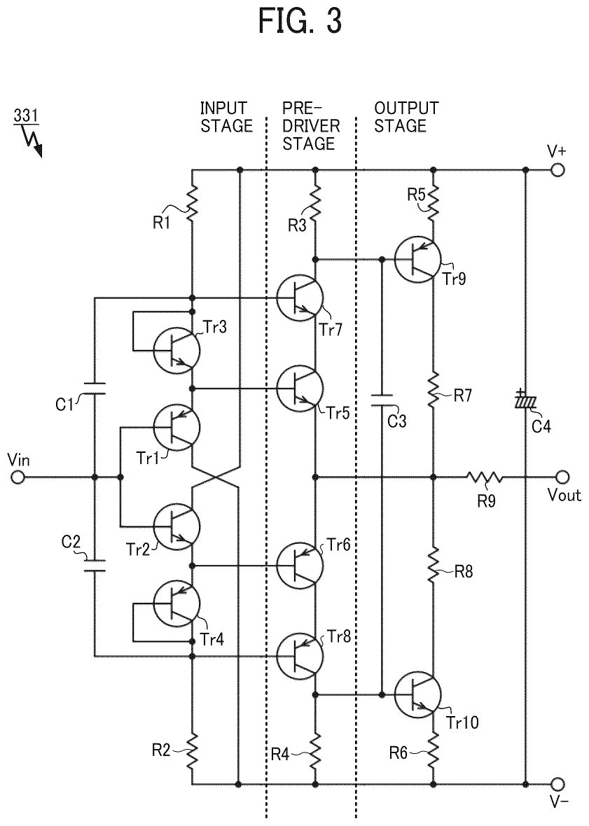

Details of the image forming unit 130 have been described above. Hereinafter, the amplifier circuit 330 included in the image forming unit 130, particularly, the current amplifier circuit 331 included in the amplifier circuit 330 will be described. The amplifier circuit 330 is preferably configured as a class-B amplifier circuit so as to reduce power consumption. Furthermore, in order to cause the recording head 340 to appropriately operate to improve the quality of an image to be formed, the amplifier circuit 330 preferably achieves both improvement in waveform reproducibility (reduction of crossover distortion) and high-speed operation. Therefore, the current amplifier circuit 331 of the amplifier circuit 330 may have a configuration illustrated in FIG. 3. FIG. 3 is a circuit diagram of the current amplifier circuit 331.

As illustrated in FIG. 3, the current amplifier circuit 331 includes an input stage, a pre-driver stage, and an output stage. Here, in the current amplifier circuit 331 illustrated in FIG. 3, it is possible to achieve improvement in waveform reproducibility (reduction of crossover distortion) and high-speed operation in a class-B amplifier circuit by providing capacitors C1 to C3 for AC coupling between bases of transistors. Note that the transistors may be bipolar transistors.

As illustrated in FIG. 3, the current amplifier circuit 331 has a diamond buffer configuration in which the input stage and the pre-driver stage each include four transistors Tr1, Tr2, Tr5, and Tr6, and perform amplification in two stages. As a result, a sufficient current amplification factor can be obtained.

In addition, it is possible to reduce base current required to flow from Vin to the input stage and reduce loss on the input stage side by increasing the number of current amplification stages with the diamond buffer configuration as illustrated in FIG. 3.

Furthermore, in the diamond buffer configuration as illustrated in FIG. 3, base-emitter voltage of the transistor Tr2 and base-emitter voltage of the transistor Tr6 are substantially equal, and thus, base-emitter voltages (Vbe) of the input stage and the pre-driver stage can complement each other. As a result, thermal fluctuation of an operating point can be offset (that is, the input voltage and output voltage of a diamond buffer become equal, and operating point voltage can be canceled). Therefore, thermal stability of the amplifier circuit can be improved.

In addition, in the pre-driver stage, it is necessary to supply a relatively large current to the output stage at a high speed. Therefore, a cascode connection configuration between the transistor Tr5 and a transistor Tr7 and a cascode connection configuration between the transistor Tr6 and a transistor Tr8 are provided in the pre-driver stage illustrated in FIG. 3. As a result, operation speed can be improved. The cascode connection configuration is referred to also as “a cascode configuration”.

Furthermore, in the input stage, a cascode bootstrap can be constructed which enables base-emitter voltages (Vbe) of the cascode-connected transistors Tr7 and Tr8 to be locked by transistors Tr3 and Tr4 that are connected from the emitter in a diode configuration, respectively, and enables class-B operation to be stabilized by the capacitors C1 and C2 for coupling with input (Vin). Construction of such a cascode bootstrap structure enables an increase in the speed of operation of the current amplifier circuit 331.

In the output stage of the current amplifier circuit 331 illustrated in FIG. 3, configuring an amplifier circuit for class-B operation allows reduction of loss in transistors without the need for idling current. In order to reduce occurrence of crossover distortion due to class-B operation and flow-through current, the output stage of the current amplifier circuit 331 in FIG. 3 is coupled by the capacitor C3 coupling the base of a transistor Tr9 and the base of a transistor Tr10. When current necessary for turning on or off the output stage transistors is excessive or insufficient, crossover distortion or flow-through current is likely to occur. However, the coupling of the transistors of the output stage by means of the capacitor C3 as illustrated in FIG. 3 enables charge (supply) or discharge (sweep) to be performed from the capacitor C3. As a result, the base current of the transistors can be stabilized, and the occurrence of crossover distortion and flow-through current can be reduced.

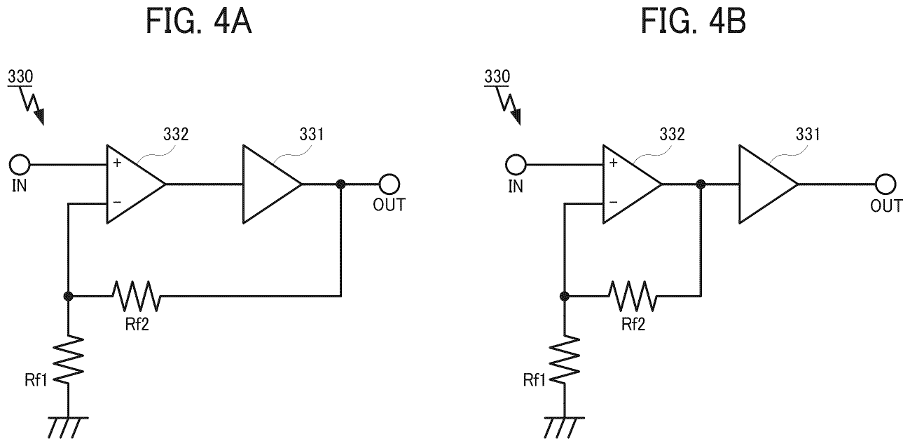

The current amplifier circuit 331 included in the amplifier circuit 330 has been described above with reference to FIG. 3. Meanwhile, the current amplifier circuit 331 illustrated in FIG. 3 operates as a drive buffer that performs only current amplification with a gain of +1. Therefore, the amplifier circuit 330, which serves as a circuit that generates drive voltage for causing the recording head 340 to operate, preferably includes a circuit that performs voltage amplification at a stage preceding the current amplifier circuit 331. Here, in the present embodiment, a configuration of the amplifier circuit 330 including the current amplifier circuit 331 and the voltage amplifier circuit 332 will be described with reference to FIGS. 4A and 4B.

FIGS. 4A and 4B are diagrams describing a feedback method of the amplifier circuit 330. FIG. 4A illustrates a configuration of a global-feedback amplifier circuit 330, and FIG. 4B illustrates a configuration of a local-feedback amplifier circuit 330. The current amplifier circuit 331 in each of FIGS. 4A and 4B may have a configuration similar to, for example, the configuration of the circuit illustrated in FIG. 3.

First, FIG. 4A will be described. FIG. 4A illustrates the global-feedback amplifier circuit 330 including the voltage amplifier circuit 332 provided at a preceding stage and the current amplifier circuit 331 provided at a subsequent stage. Negative feedback of the output of the current amplifier circuit 331 is provided to form a loop, and feedback resistors Rf1 and Rf2 are provided, as illustrated in FIG. 4A. In the current amplifier circuit 331 as illustrated in FIG. 3, the output stage is emitter-grounded. Thus, output impedance increases. Therefore, adoption of the configuration of the global-feedback amplifier circuit 330 as illustrated in FIG. 4A allows output impedance to be reduced due to the effect of negative feedback.

Next, FIG. 4B will be described. FIG. 4B illustrates the local-feedback amplifier circuit 330 including the voltage amplifier circuit 332 provided at a preceding stage and the current amplifier circuit 331 provided at a subsequent stage.

Negative feedback of the output of the voltage amplifier circuit 332 is provided to form a loop, and feedback resistors Rf1 and Rf2 are provided, as illustrated in FIG. 4B. Here, a nozzle of the recording head 340 is generally configured as a capacitive load. Therefore, in the case of the global-feedback amplifier circuit 330 as illustrated in FIG. 4A, for example, a reflection response component from a piezo electrode is fed back to the voltage amplifier circuit 332. As a result, waveform disturbance occurs. In addition, in the case of the global-feedback amplifier circuit 330, resonance poles are formed by the feedback resistors Rf1 and Rf2 and load capacitance, and thus, oscillation is likely to occur. Therefore, adoption of the configuration of the local-feedback amplifier circuit 330 as illustrated in FIG. 4B allows effect due to the load capacitance to be reduced.

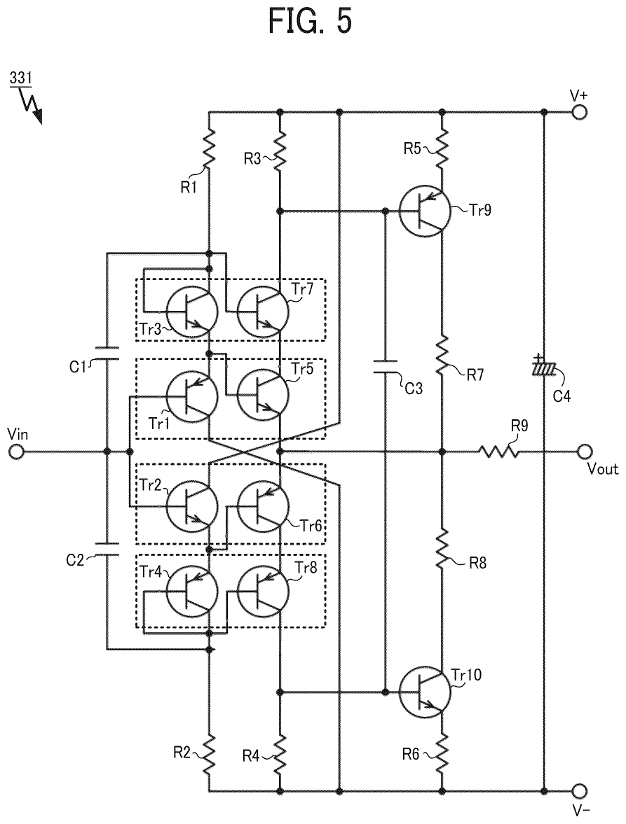

The basic configuration of the present embodiment has been described above. Meanwhile, the configuration of the current amplifier circuit 331 illustrated in FIG. 3 is an example, and does not particularly limit the embodiment. Therefore, the current amplifier circuit 331 may have various modifications. Hereinafter, modifications will be described with reference to FIGS. 5 to 11. In the following description of the modifications, differences from the configuration of the embodiment illustrated in FIG. 3 will be mainly described.

First, FIG. 5 is described. FIG. 5 is a circuit diagram of a current amplifier circuit 331 according to a first modification. The first modification is configured as a thermal coupling circuit of a transistor so as to improve thermal stability of the amplifier circuit 330. In the current amplifier circuit 331 of FIG. 3, the collector of the transistor Tr1 is connected to the output stage side of a resistor R2, and the collector of the transistor Tr2 is connected to the output stage side of a resistor R1. Meanwhile, the current amplifier circuit 331 of the first modification illustrated in FIG. 5 has a configuration in which the collector of the transistor Tr1 is connected to a V-line between resistors R4 and R6, and the collector of the transistor Tr2 is connected to a V+line between resistors R3 and R5.

In the first modification, adoption of the configuration illustrated in FIG. 5 makes it possible to perform operation of causing base-emitter voltages of two transistors (that is, a combination of Tr1 and Tr5, a combination of Tr2 and Tr6, a combination of Tr3 and Tr7, and a combination of Tr4 and Tr8) in each broken-line region to complement each other. Thermal coupling of two transistors in each broken-line region makes it possible to offset the temperature fluctuation of base-emitter voltage and to further stabilize the operating point. Thermal coupling can be implemented by, for example, a method for physically coupling packages of two transistors (such as a method for coupling two transistors with an adhesive or the like or a method for dissipating heat on the same radiator), or a method for arranging collector terminals of two transistors close to each other and coupling the collector terminals via a pattern of a substrate. In addition, thermal coupling may be implemented by means of a composite transistor including two identical transistors housed in a single package.

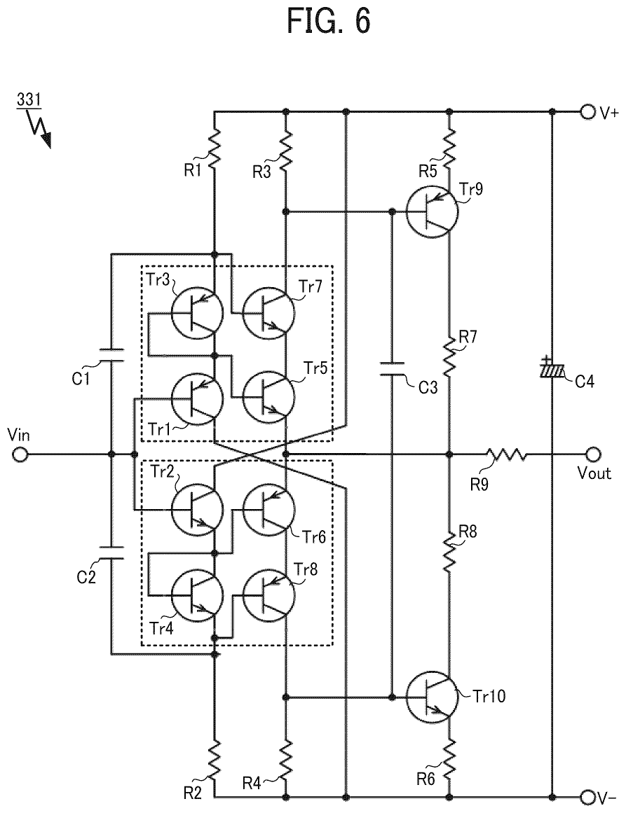

Next, FIG. 6 will be described. FIG. 6 is a circuit diagram of a current amplifier circuit 331 according to a second modification. The second modification can further improve thermal stability as compared with the configuration of the first modification illustrated in FIG. 5. In the second modification illustrated in FIG. 6, the polarities of the transistors Tr3 and Tr4 have been changed from the configuration of the first modification. In the first modification, the polarities of the transistors Tr3 and Tr4 are the same as the polarities of the transistors Tr7 and Tr8, respectively. Meanwhile, as illustrated in FIG. 6, transistors with different polarities are used in the second modification.

In the second modification, four transistors in each broken-line region may be combined into a composite transistor including two complementary pairs. That is, the transistors Tr1, Tr3, Tr5, and Tr7 may be combined to serve as a composite transistor, and the transistors Tr2, Tr4, Tr6, and Tr8 may be combined to serve as a composite transistor. Alternatively, pairs of transistors in a diamond buffer configuration portion and a cascode bootstrap portion may each be divided into two to form a complementary pair.

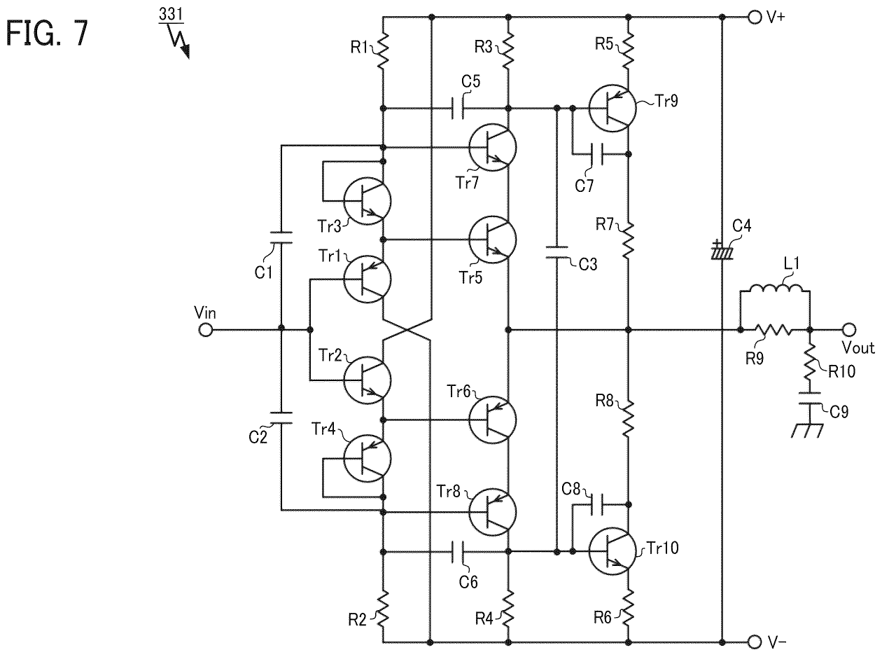

Next, FIG. 7 will be described. FIG. 7 is a circuit diagram of a current amplifier circuit 331 according to a third modification. The third modification is a configuration for performing phase compensation in the configuration of the embodiment illustrated in FIG. 3. Capacitors C5 to C8 have been further added to the configuration of FIG. 3 to obtain the current amplifier circuit 331 illustrated in FIG. 7. The transistors Tr7 and Tr8 serving as cascode transistors and the transistors Tr9 and Tr10 of the output stage can be mirror-compensated by the capacitors C5 to C8. In particular, in the third modification, addition of the capacitors C5 to C8 allows load capacitance to be increased and oscillation to be prevented.

In the third modification, a filter may be provided in the output stage so as to perform phase compensation for the load. For example, a Zobel filter including a series circuit of a resistor R10 and a capacitor C9, and an isolator filter including a parallel circuit of a resistor R9 and an inductance L1 can be provided as illustrated in FIG. 7. Providing the filter as illustrated in FIG. 7 makes it possible to compensate a capacitance component and an inductance component deriving from the load.

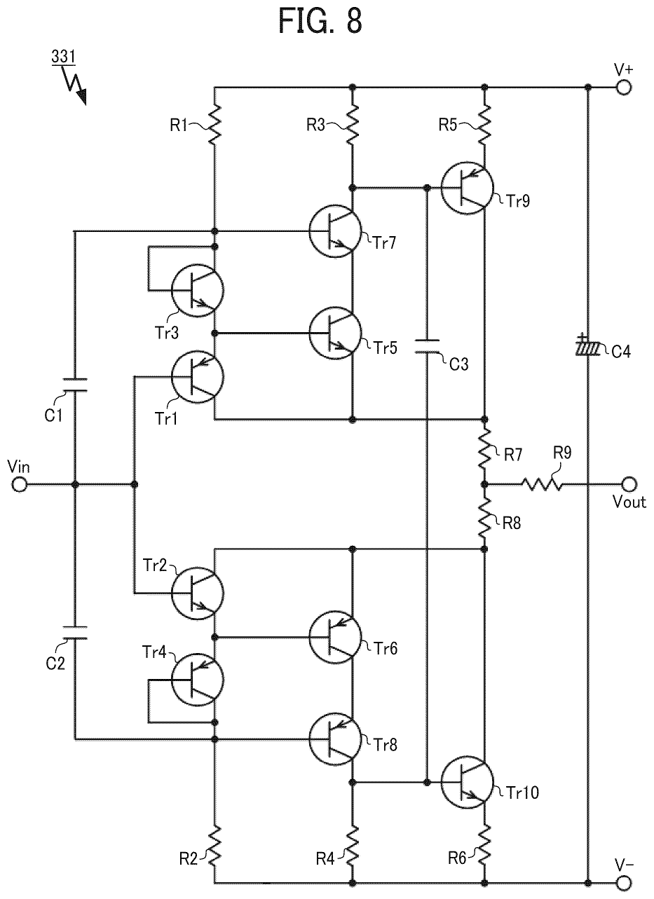

Next, FIG. 8 will be described. FIG. 8 is a circuit diagram of a current amplifier circuit 331 according to a fourth modification. In the fourth modification, each transistor terminal of a diamond buffer portion is shared with output stage transistors. In the current amplifier circuit 331 of the fourth modification, the collector terminal of the transistor Tr1 and the collector terminal of the transistor Tr9 are connected, and the collector terminal of the transistor Tr2 and the collector terminal of the transistor Tr10 are connected, as illustrated in FIG. 8. In the other examples, the collectors of the transistors Tr1 and Tr2 are connected to the V-line and the V+line, respectively. Meanwhile, as illustrated in FIG. 8, the collectors of the transistors Tr1 and Tr2 are connected to transistors of the output stage. As a result, loss can be reduced in the transistors Tr1 and Tr2.

In the fourth modification, the transistors Tr1 and Tr2 may be replaced with junction field effect transistors (JFET). Use of JFETs as transistors of the input stage makes it possible to increase input impedance to the voltage amplifier circuit 332 of the preceding stage, and to achieve reduction of loss in the voltage amplifier circuit 332 and an increase in the speed thereof.

In the fourth modification illustrated in FIG. 8, there are multiple local feedback paths. It is thus preferable to perform phase compensation or the like as a countermeasure against oscillation.

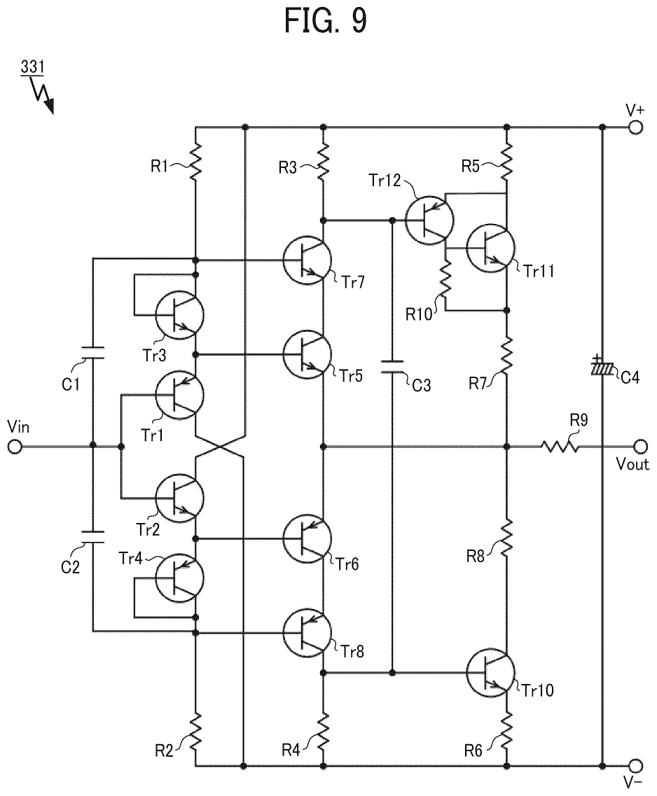

Next, FIG. 9 will be described. FIG. 9 is a circuit diagram of a current amplifier circuit 331 according to a fifth modification. In the fifth modification, the transistor Tr9 of the output stage of the current amplifier circuit 331 in FIG. 3 has been replaced with two transistors Tr11 and Tr12 with different polarities. In the current amplifier circuit 331 of FIG. 3, the PNP transistor Tr9 and the NPN transistor Tr10 form a complementary push-pull. Meanwhile, in consideration of marketability, availability, and the like, it may be preferable to use an NPN transistor (particularly in the case of a large-current transistor). Therefore, in the current amplifier circuit 331 in the fifth modification, the transistor Tr9 of FIG. 3 has been replaced with the transistors Tr11 and Tr12 to form a quasi-complementary push-pull configuration, as illustrated in FIG. 9.

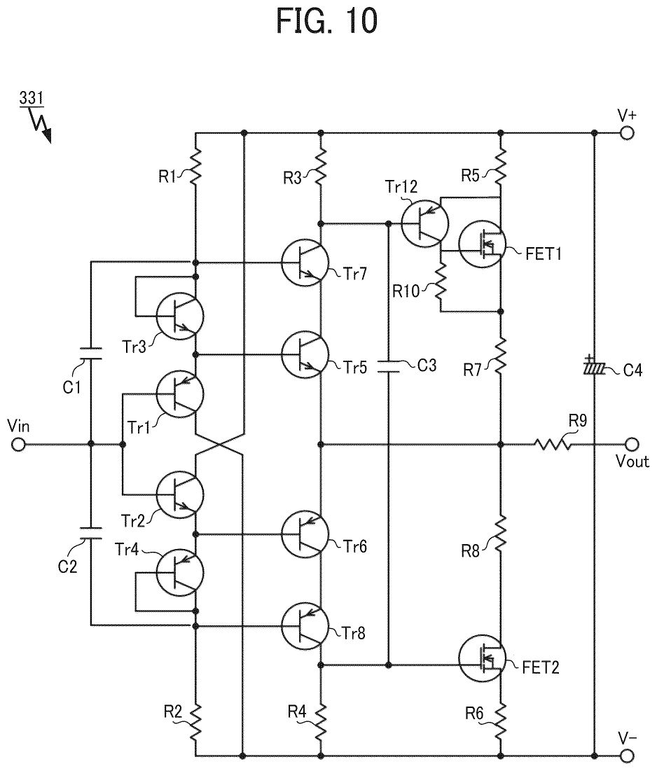

Next, FIG. 10 will be described. FIG. 10 is a circuit diagram of a current amplifier circuit 331 according to a sixth modification. In the sixth modification, the two NPN transistors Tr10 and Tr11 in the fifth modification have been replaced with N-type MOSFETs (field effect transistors FET1 and FET2). For example, the sixth modification is effective in a case where output voltage is high or in a case where higher speed is achieved. In the current amplifier circuit 331 illustrated in FIG. 10, it is possible to reduce cost by using only N-type MOSFETs as the quasi-complementary push-pull configuration from the viewpoint of the marketability and availability of MOSFETs. In addition, the field effect transistors FET1 and FET2 may be MOSFETs or the like using SiC or GaN with lower power consumption.

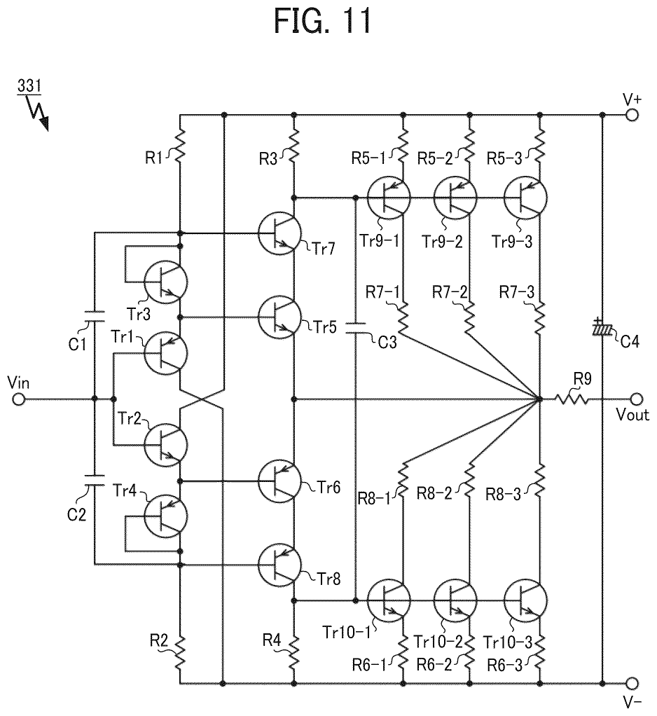

Next, FIG. 11 will be described. FIG. 11 is a circuit diagram of a current amplifier circuit 331 according to a seventh modification. In the seventh modification, transistors of the output stage can be connected in parallel. That is, as illustrated in FIG. 11, multiple transistors included in the output stage are connected in parallel. In the exemplary circuit illustrated in FIG. 11, transistors Tr9-1, Tr9-2, and Tr9-3 are connected in parallel, and transistors Tr10-1, Tr10-2, and Tr10-3 are connected in parallel. In accordance with the parallel connection of the transistors, collector-side resistors and emitter-side resistors are also connected in parallel. With the configuration in which the multiple transistors are connected in parallel in the output stage as described above, drive current can be supplied by the multiple transistors even when a large current flows. In addition, since loss in each transistor can be reduced by parallel connection, transistors can be shared between the input stage and the output stage. Furthermore, use of multiple transistors that handle relatively small power instead of transistors that handle relatively large power makes it possible to disperse heat loss per transistor to improve the degree of freedom in substrate arrangement. As a result, space on a substrate can be saved.

According to the above-described embodiment of the present disclosure, it is possible to provide a current amplifier circuit, an amplifier circuit, and an image forming apparatus with improved speed and stability in a class-B operation amplifier circuit that drives an inkjet head.

A current amplifier circuit includes: a first transistor (Tr1) including a first base terminal; and a second transistor (Tr2) including a second base terminal; and a capacitor (C1, C2) coupling the first base terminal of the first transistors (Tr1) and the second base terminal of the second transistor (Tr2), to perform class-B operation. The current amplifier circuit further includes: a third transistor (Tr5) connected to the first transistor (Tr1); and a fourth transistor (Tr6) connected to the second transistor (Tr2), in a diamond buffer configuration. The current amplifier circuit further includes: a fifth transistor (Tr7) connected to the third transistor (Tr5) in a cascode configuration; and a sixth transistor (Tr8) connected to the fourth transistor (Tr6) in a cascode configuration.

The current amplifier circuit further includes: a seventh transistor (Tr3) connected to the first transistor (Tr1) in a diode configuration, the fifth transistors (Tr7); and the capacitor (C1), form a bootstrap. The first transistor (Tr1) and the third transistor (Tr5) are thermally coupled. The current amplifier circuit further includes: a seventh transistor (Tr9) connected to the fifth transistor (Tr7), wherein a terminal of the third transistor (Tr5); a terminal of the fifth transistor (Tr7); and a terminal of the seventh transistor (Tr9) are connected.

The current amplifier circuit further includes: an input stage including the first transistor (Tr1) and the second transistor (Tr2); a pre-driver stage including the third transistor (Tr5) and the fourth transistor (Tr6); and an output stage including a filter circuit (R10, C9). The current amplifier circuit further includes: two transistors (Tr11, Tr12) forming a push-pull configuration with same polarity; an input stage including the first transistor (Tr1) and the second transistor (Tr2); a pre-driver stage including the third transistor (Tr5) and the fourth transistor (Tr6); and an output stage including the two transistors. The current amplifier circuit further includes: fifth transistors connected in parallel; an input stage including the first transistor (Tr1) and the second transistor (Tr2); a pre-driver stage including the third transistor (Tr5) and the fourth transistor (Tr6); and an output stage including the fifth transistors.

An amplifier circuit includes: the current amplifier circuit; and a voltage amplifier circuit connected to the current amplifier circuit, wherein the voltage amplifier circuit is at a stage preceding the current amplifier circuit, and an output of the current amplifier circuit is negatively fed back to the voltage amplifier circuit. An amplifier circuit includes: the current amplifier circuit according to claim 1; and a voltage amplifier circuit connected to the current amplifier circuit, wherein the voltage amplifier circuit is at a stage preceding the current amplifier circuit, and an output of the voltage amplifier circuit is negatively fed back to the voltage amplifier circuit.

An image forming apparatus includes: a liquid discharge apparatus including: the amplifier circuit according to claim 10, anda liquid discharge head connected to the amplifier circuit, wherein the amplifier circuit outputs a signal to the liquid discharge head to discharges a liquid.

Although an embodiment of the present disclosure has been described above, the present disclosure is not limited to the embodiment described above, and various modifications may be made without departing from the spirit and scope of the present disclosure that can be estimated by the skilled person. Such modifications exhibiting functions and effects of the present disclosure are within the scope of the present disclosure.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

1. A current amplifier circuit comprising:
a first transistor including a first base terminal; and
a second transistor including a second base terminal; and
a capacitor coupling the first base terminal of the first transistor and the second base terminal of the second transistor,
to perform a class-B operation.

2. The current amplifier circuit according to claim 1, further comprising:
a third transistor connected to the first transistor; and
a fourth transistor connected to the second transistor,
in a diamond buffer configuration.

3. The current amplifier circuit according to claim 2, further comprising:
a fifth transistor connected to the third transistor in a cascode configuration; and
a sixth transistor connected to the fourth transistor in a cascode configuration.

4. The current amplifier circuit according to claim 3, further comprising:
a seventh transistor connected to the first transistor in a diode configuration,
the fifth transistor; and
the capacitor,
form a bootstrap.

5. The current amplifier circuit according to claim 4,
wherein the first transistor and the third transistor are thermally coupled.

6. The current amplifier circuit according to claim 3, further comprising:
a seventh transistor connected to the fifth transistor,
wherein a terminal of the third transistor;
a terminal of the fifth transistor; and
a terminal of the seventh transistor are connected.

7. The current amplifier circuit according to claim 2, further comprising:
an input stage including the first transistor and the second transistor;
a pre-driver stage including the third transistor and the fourth transistor; and
an output stage including a filter circuit.

8. The current amplifier circuit according to claim 2, further comprising:
two transistors forming a push-pull configuration with same polarity;
an input stage including the first transistor and the second transistor;
a pre-driver stage including the third transistor and the fourth transistor; and
an output stage including the two transistors.

9. The current amplifier circuit according to claim 2, further comprising:
fifth transistors connected in parallel;
an input stage including the first transistor and the second transistor;
a pre-driver stage including the third transistor and the fourth transistor; and
an output stage including the fifth transistors.

10. An amplifier circuit comprising:
the current amplifier circuit according to claim 1; and
a voltage amplifier circuit connected to the current amplifier circuit,
wherein the voltage amplifier circuit is at a stage preceding the current amplifier circuit, and
an output of the current amplifier circuit is negatively fed back to the voltage amplifier circuit.

11. An amplifier circuit comprising:
the current amplifier circuit according to claim 1; and
a voltage amplifier circuit connected to the current amplifier circuit,
wherein the voltage amplifier circuit is at a stage preceding the current amplifier circuit, and
an output of the voltage amplifier circuit is negatively fed back to the voltage amplifier circuit.

12. An image forming apparatus comprising:
a liquid discharge apparatus including:
the amplifier circuit according to claim 10, and
a liquid discharge head connected to the amplifier circuit,
wherein the amplifier circuit outputs a signal to the liquid discharge head to discharges a liquid.

13. An image forming apparatus comprising:
a liquid discharge apparatus including:
the amplifier circuit according to claim 11, and
a liquid discharge head connected to the amplifier circuit,
wherein the amplifier circuit outputs a signal to the liquid discharge head to discharges a liquid.
